(19) United States
(12) Patent Application Publication
(10) Pub. No.: US 2006/0192234 A1
(43) Pub. Date: Aug. 31, 2006

(54) Solid-state imaging device

(75) Inventor: Ryouhei Miyagawa, Muko (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/250,379

(22) Filed: Oct. 17, 2005

(30) Foreign Application Priority Data
Feb. 28, 2005 (JP) 2005-052843

(51) Int. Cl. H01L 31/113

(52) U.S. Cl. 257/292

(57) ABSTRACT

Pixels have a photodiode 1, a transfer gate electrode 2 for transferring charges accumulated in the photodiode 1, a floating diffusion section 3 for accumulating the charge transferred by the transfer gate electrode 2, an amplification transistor 15 in which a gate electrode is connected to the floating diffusion section 3, and a reset transistor 14 for resetting a potential of the floating diffusion section 5. A gate length of the amplification transistor 15 is shorter than a gate length of a transistor, among transistors comprising the peripheral circuitry region, whose gate insulating film thickness is a same as a gate insulating film thickness of the amplification transistor 15 and which has a minimum gate length.

### BACKGROUND OF THE INVENTION

1. Field of the Invention

The present invention relates to a solid-state imaging device having a plurality of photoelectric conversion elements disposed therein and more particularly, to a technique for enhancing sensitivity by noise reduction and for miniaturizing a pixel size.

2. Description of the Background Art

In recent years, an amplification-type MOS image sensor has been utilized for coping with high voltage operations or the like. FIG. 7 shows a circuit configuration of pixels in the conventional amplification-type MOS image sensor, for example, disclosed in Japanese Laid-Open Patent Publication No. 2003-46865.

The conventional MOS image sensor includes a photodiode 21, a transfer transistor 22 for transferring charges from the photodiode 21 to a floating diffusion section 23 (hereinafter, referred to as FD 23), are set transistor 24 for resetting a potential of the FD 23, and an amplification transistor 25 for current-amplifying the potential of the FD 23. A configuration having a selection transistor for selecting rows (or columns) has also been known, though not shown here.

Among these pixel configuration elements, particularly important for an image sensor is the amplification transistor 25. Because a source follower output circuit comprises the amplification transistor 25 and a load transistor 26 which is disposed outside a pixel region, if a gain of the amplification transistor 25 fluctuates, sensitivity of pixels will fluctuate, causing noise and thereby deteriorating image quality.

In a transistor, generally, if a physical gate length is short, an effective gate length will fluctuate due to short channel effect. On the amplification transistor 25, the fluctuation in the effective gate length directly leads to the fluctuation in the gain. Therefore, in the conventional MOS image sensor, for example, disclosed in Japanese Laid-Open Patent Publication No. 10-150182, a physical gate length of the amplification transistor 25 is usually designed to be the minimum gate length in process rule (design rule) thereof or more. Hereinafter, a physical gate length is referred to simply as a gate length.

Specific descriptions will be given as follows. First, a gate length of the amplification transistor 25, which determines analogue properties in pixels, is designed to be a gate length or more, of transistors in a peripheral circuit. For example, when the peripheral circuit outside the pixel region is configured with a plurality of transistors, using a multi-gate process, whose gate oxide thicknesses vary, the gate length of the amplification transistor 25 is designed to be a gate length or more, of a transistor whose gate oxide thickness is a same as that of the amplification transistor 25.

And when compared with gate lengths of other transistors in pixels, the gate length of the amplification transistor 25 is designed to be a gate length or more, of the transistors other than the amplification transistor 25, that is, the reset transistor 24 and the selection transistor. Here, whereas the amplification transistor 25 directly affects the analogue properties of the MOS image sensor, the reset transistor 24 and the selection transistor do not because the reset transistor 24 and the selection transistor function mainly as switches. Thus even when the reset transistor and the selection transistor are designed with the minimum gate length in the process rule, no particular problem will arise.

A gate length of the transfer transistor 22 is usually designed to be longer than gate lengths of other transistors (the reset transistor 24, the selection transistor, and the amplification transistor 25) in a pixel cell. An impurity diffusion region of the photodiode 21, which corresponds to a source in the transfer transistor 22, is designed so as to be more deeply disposed than those of regions of a source and a drain of the other transistors, in order to collect photoproduction electrons.

On the other hand, in order to reduce a chip size, gate lengths of transistors disposed in the peripheral circuit which is a logic circuit such as a pulse generation circuit for driving pixels are designed with the minimum length in the process rule.

However, shortening the gate length of the amplification transistor 25, because of the limitations described above, has hindered the amplification transistor 25 from being miniaturized and thereby the pixels from being miniaturized.

### SUMMARY OF THE INVENTION

Therefore, in order to solve the above described problems in the conventional amplification-type MOS image sensor, an object of the present invention is to provide a solid-state imaging device in which a relationship between a gate length of an amplification transistor and gate lengths of other transistors is defined and a fluctuation in a gain is controlled, but at a same time pixel miniaturization is realized.

In order to solve the above problems, the solid-state imaging device according to the present invention includes a pixel region having a plurality of pixels arrayed therein and a peripheral circuit for driving or scanning the pixels, the pixels at least having: a photodiode; a transfer gate electrode for transferring charges accumulated in the photodiode; a floating diffusion section for accumulating the charge transferred by the transfer gate electrode; an amplification transistor in which a gate electrode is connected to the floating diffusion section; and a reset transistor for resetting a potential of the floating diffusion section, a gate length of the amplification transistor being shorter than a gate length of a transistor, among transistors comprising the peripheral circuit, whose gate insulating film thickness is a same as a gate insulating film thickness of the amplification transistor and which has a minimum gate length.

Another solid-state imaging device according to the present invention includes a pixel region having a plurality of pixels arrayed therein and a peripheral circuit for driving or scanning the pixels, the pixels at least having: a photodiode; a transfer gate electrode for transferring charges accumulated in the photodiode; a floating diffusion section for accumulating the charge transferred by the transfer gate electrode; an amplification transistor in which a gate electrode is connected to the floating diffusion section; and a reset transistor for resetting a potential of the floating diffusion section, a gate length of the amplification transistor being shorter than gate lengths of other transistors in the pixels.

Among the plurality of the pixels, at least two neighboring pixels preferably share at least the amplification transistor and the reset transistor.

A selection transistor for selecting an output from each of the two neighboring pixels may be further provided.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating a pixel layout in a solid-state imaging device according to a first embodiment of the present invention;

FIG. 2 is a diagram illustrating effects of the present invention and plotting a fluctuation in a gain, which occurs when changing a gate length of an amplification transistor;

FIG. 3 is a diagram illustrating effects of the present invention and plotting gains depending on gate lengths of the amplification transistor;

FIG. 4 is a diagram illustrating effects of the present invention and illustrating a mechanism of dependence of the gains of the amplification transistor on the gate lengths;

FIG. 5 is a plan view illustrating a pixel layout in a solid-state imaging device according to a second embodiment of the present invention.

FIG. 6 is a plan view illustrating an example of a modified pixel layout in the second embodiment of the present invention; and

FIG. 7 is a diagram illustrating a circuit configuration of pixels in the conventional amplification-type MOS image sensor.

### DESCRIPTION OF THE PREFERRED EMBODIMENTS

### First Embodiment

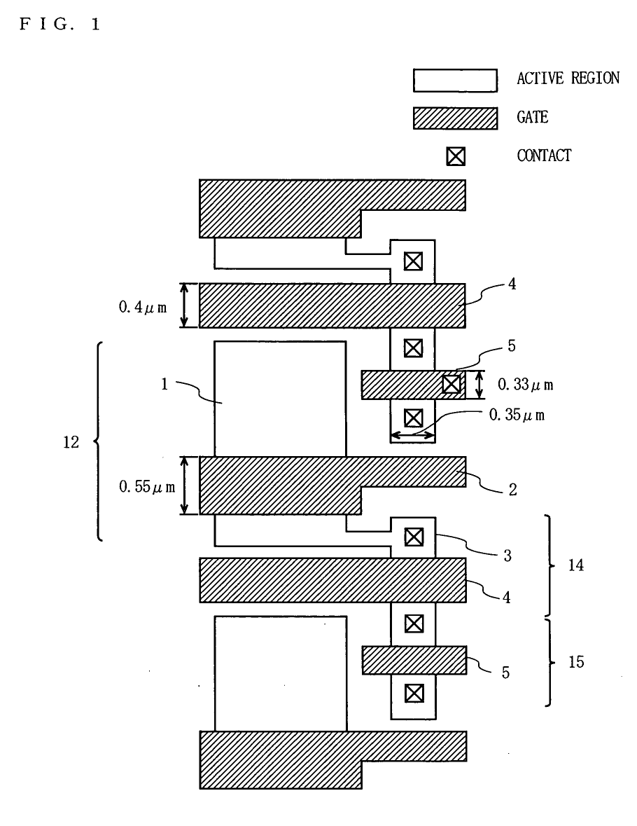

FIG. 1 is a plan view illustrating a pixel layout in a solid-state imaging device (MOS image sensor) according to a first embodiment of the present invention. More specifically, FIG. 1 shows a layout of active regions, gates, and contacts, and illustrates a layout, mainly, of a photodiode 1, a transfer gate 2 of a transfer transistor 12, a floating diffusion section 3 (hereinafter referred to as an FD section 3), reset gates 14 of are set transistor 14, and amplification gates 5 of an amplification transistor 15. Here, the transfer gate 2 is to transfer to the FD section 3 charges accumulated by the photodiode 1. The amplification gates 5 are electrically connected to the FD section 3. The reset transistor 14 is to reset a potential of the FD section 3.

As shown in FIG. 1, a physical gate length (hereinafter, simply referred to as a gate length) of the transfer gate 2 and a gate length of the reset gate 4 are, for example, 0.55 μm and 0.4 μm, respectively, and a gate length of the amplification gates 5 is, for example, 0.33 μm. Thus the solid-state imaging device according to the present embodiment is characterized in that the gate length of the amplification gates 5 is shorter than those of the transfer gate 2 and the reset gate 4.

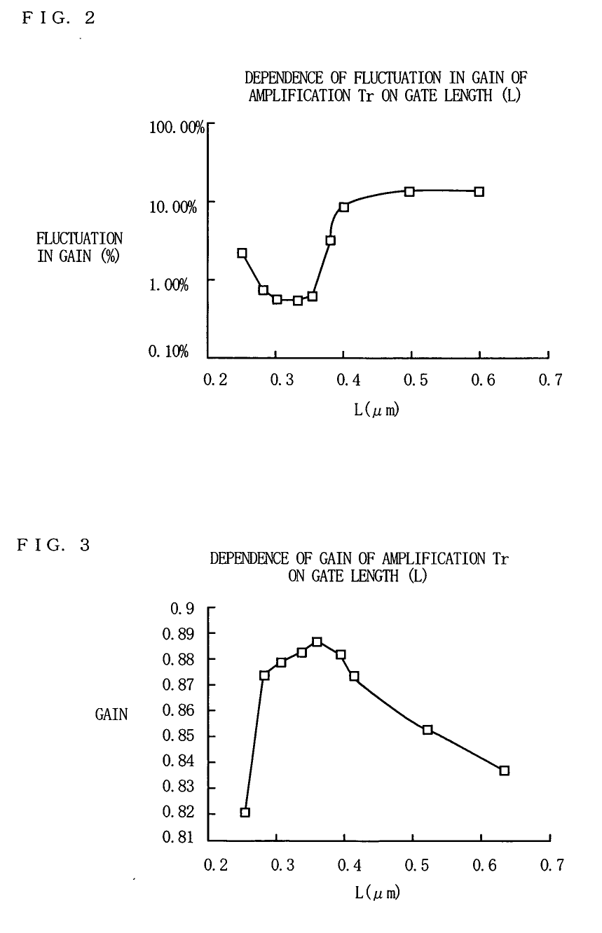

Referring to FIG. 2 and FIG. 3, specific descriptions on the above characteristic will be given. FIG. 2 and FIG. 3 are diagrams illustrating effects of the present invention, FIG. 2 plotting a fluctuation in a gain depending on the gate lengths L of the amplification transistor 15, FIG. 3 plotting the gain depending on the gate lengths L of the amplification transistor 15.

The amplification transistor 15 is a transistor whose driving voltage is 3V and whose thickness of a gate oxide film is 9 nm. A minimum gate length in this process rule is designed as 0.4 μm.

In order to measure properties shown in FIG. 2 and FIG. 3, a drain voltage of the amplification transistor 15 was set as 2.9V and a source was connected to a current source whose current value was set as 5 μA. The gate voltage of the amplification transistor 15 was varied in a range of 2.9V to 2.1V corresponding to an actual operation in pixels because the FD potential varied in a range of 2.9V to 2.1V when a sensor was on. A gain of the amplification transistor 15 was derived by dividing a varied source potential of the amplification transistor 15, which was measured at this time, by a varied FD potential.

The gains and fluctuating values of the respective gate lengths in FIG. 2 and FIG. 3 were obtained by taking data at 60 points in an 8-inch wafer on same-sized transistors. A fluctuating gain value was obtained by dividing a standard error of each datum by an average value.

As shown in FIG. 2, it was found that the fluctuation of the gain of the amplification transistor 15 was minimized when the gate length was in a range of 0.3 μm to 0.35 μm. When the gate length was shorter than 0.3 μm, the gain greatly fluctuated, which was due to short channel effect. On the other hand, the gain was lower in this range, as shown in FIG. 3, due to so-called reverse short channel effect.

The present inventors found at this time that the fluctuation was greater also when the gate length was longer than 0.35 μm. Specifically, when the gate length was in a range of 0.3 μm to 0.35 μm, the gain was maximized and further the fluctuation in the gain was minimized.

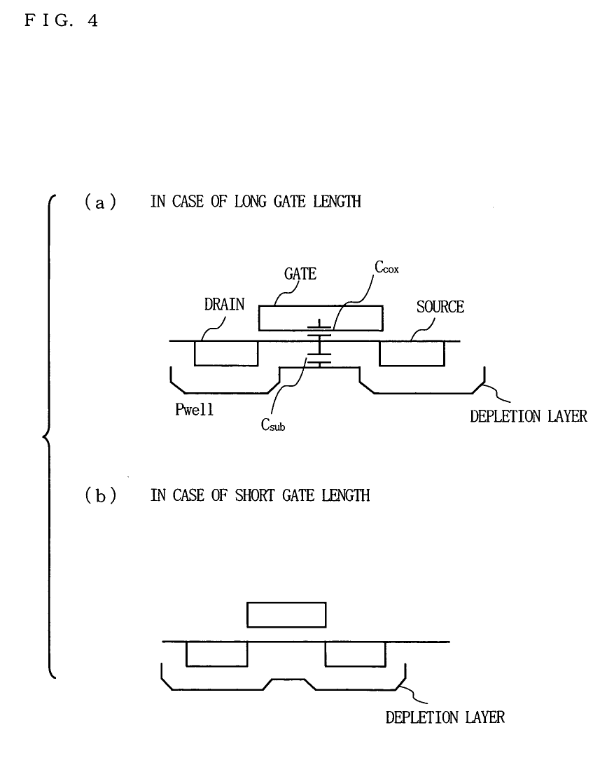

The reason for this will be described with reference to FIG. 4. FIG. 4 is a diagram illustrating a mechanism of dependence on the gate length of the amplification transistor 15. As shown in FIG. 4(a), the gain of the amplification transistor 15 depends on capacitance Cox between a gate and a channel of the transistor and capacitance Csub in between a channel and a back-gate (Pwell). In other words, the gain can be approximated by Cox/(Cox+Csub). Here the capacitance Cox depends on a thickness of gate oxide.

When the gate length is longer than 0.35 μm, respective capacitance Cox and Csus which determine the gain are not influenced by a source and a drain, as shown in FIG. 4(a). On the other hand, when the gate length is shorter than 0.35 μm, as shown in FIG. 4(b), the source and the drain are located in vicinity to each other, enlarging a depletion layer under the channel and thereby the capacitance Csub becomes smaller. Thus when the gate length is in the range of 0.3 μm to 0.35 μm, the gain approaches 1, reducing the fluctuation in the gain.

When the gate length is less than 0.3 μm, punch-through may occur due to the short channel effect and the fluctuation in the gate lengths caused during the process of manufacturing semiconductors affects dominantly the fluctuation in the gain.

In general, when the gate length is shorter than a minimum gate length in the process rule, the fluctuation in properties is greater due to the short channel effect. However, the amplification transistors 15 used in the MOS image sensor operates in a range of 1V to 2V of a source potential, because the source is connected to VSS (ground potential). In other words, a voltage between the source and the drain is around 2V even at maximum and is lower than a VDD−VSS potential difference (2.9V in the present embodiment). Therefore even when the gate length is the minimum gate length in the process rule (0.4 μm in the present embodiment) or shorter, no punch-through may occur due to the short channel effect.

As a result of examination, the present inventors confirmed that when the gate length was 0.3 μm or more, no effect of the punch-through was exerted. Thus in the transistor whose gate length is 0.3 μm to 0.35 μm, the fluctuation in the gain is minimized.

On the other hand, if a transistor whose gate length is 0.3 μm to 0.35 μm is used in a logic circuit in a peripheral circuitry region of pixels, a potential difference (VSS-VDD) between a source and a drain will arise, resulting in a hot carrier caused by a flowing current. This may cause a fluctuation in a threshold voltage of a transistor and thereby cause the transistor to malfunction, leading to a problem with reliability of a solid-state imaging device.

In the present embodiment, gate lengths of the transistors other than the amplification transistor 15 in a pixel region are designed to be the minimum gate length in the process rule or more. As shown in FIG. 1, a length of the gate 4 of the reset transistor 14 is 0.4 μm which is the minimum gate length in the process rule. On the other hand, the gate length of the amplification transistor 15 is designed to be 0.33 μm which is shorter than the minimum gate length in the process rule. As already stated in the description of FIG. 3, a preferable gate length of the amplification transistor 15 is 0.3 μm to 0.35 μm.

Similarly, also in the peripheral circuitry region, whereas gate lengths of the other transistors having gate oxide whose thickness is the same as that (9 nm) of the amplification transistor 15 are designed to be 0.4 μm, which is the minimum gate length in the process rule, or more, the gate length of the amplification transistor 15 is designed to be less than the minimum gate length in the process rule.

As described above, according to the present embodiment of the solid-state imaging device, the gate length of the amplification transistor is designed to be shorter than those of the other transistors, thus realizing a highly-sensitive MOS image sensor with less fluctuation in pixel sensitivity and reduced noise. And a short gate length can be set, enabling miniaturization of pixels and realizing a high-definition MOS image sensor.

The reason why the transistor, among the transistors in the peripheral circuitry region, whose gate oxide thickness is the same as that of the amplification transistor 15 is chosen to be compared is as follows.

When required capability and driving voltage of a transistor greatly differ between a pixel region and a peripheral circuitry region, a transistor tends to be formed with each suited gate oxide thickness. This is a so-called multi-gate process.

However, thinner gate oxide increases capacitance and thereby the short channel effect may be unlikely to accrue. Therefore when a gate oxide thickness of a transistor in a peripheral circuitry region is set to be thinner than that in a pixel region, the short channel effect is suppressed, thereby enabling a gate length of the transistor in the peripheral circuitry region to be shortened. In such a case, a gate length of the amplification transistor in pixels is likely to be longer than that of the transistor in the peripheral circuitry region. For this reason, the transistor whose gate oxide thickness is the same as that of the amplification transistor 15 is chosen to be compared.

### Second Embodiment

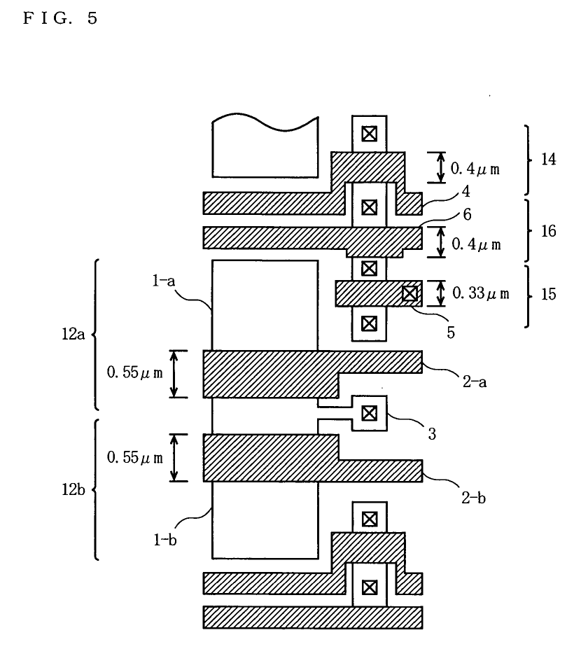

FIG. 5 shows the plan view of the layout of pixels in the solid-state imaging device (the MOS image sensor) according to the second embodiment of the present invention. A configuration of the solid-state imaging device according to the present embodiment is different from that according to the first embodiment in that only one FD section 3 is disposed for two transfer transistors 12a and 12b and two pixels neighboring above and below share an amplification transistor 15, a selection transistor 16, and a reset transistor 14.

Charges accumulated in the two photodiodes 1-a and 1-b are transferred to the FD section 3 when voltages are applied to respective transfer gates 2-a and 2-b. The FD section 3 is connected to the reset transistor 14 for resetting a FD potential. The FD section 3 is connected to an amplification gate 5 of the amplification transistor 15. The selection transistor 16 is connected to a drain side of the amplification transistor 15.

In the present embodiment, the same process rule as in the first embodiment is also applied and a minimum gate length is 0.4 μm when a gate oxide thickness is 9 nm.

Gate lengths of the selection transistor 16 and the reset transistor 14 shown in FIG. 5 are designed to be 0.4 μm and a gate length of the amplification transistor 15 is designed to be 0.33 μm similarly to the first embodiment.

According to the present embodiment of the solid-state imaging device, a fluctuation in a gain is suppressed, reducing noise, and not only miniaturization of pixels is realized but also the number of transistors per pixel can be decreased because two pixels share transistors, thus enabling pixels to be further miniaturized.

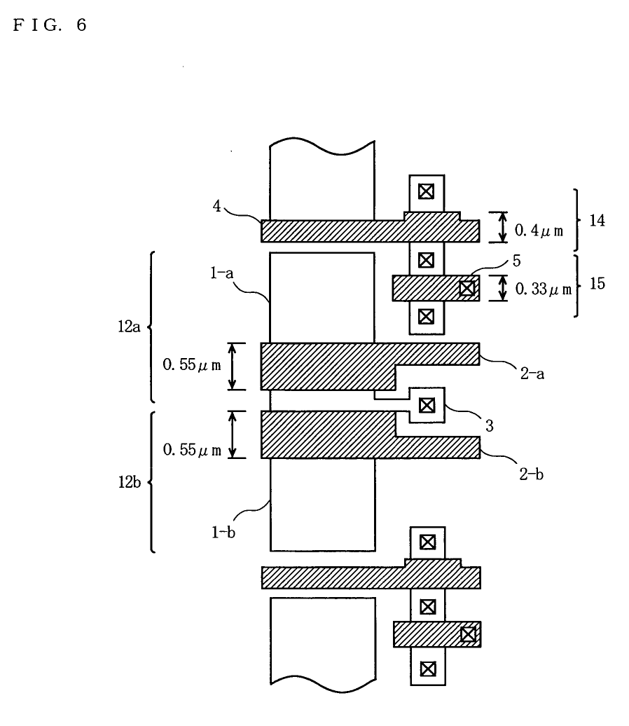

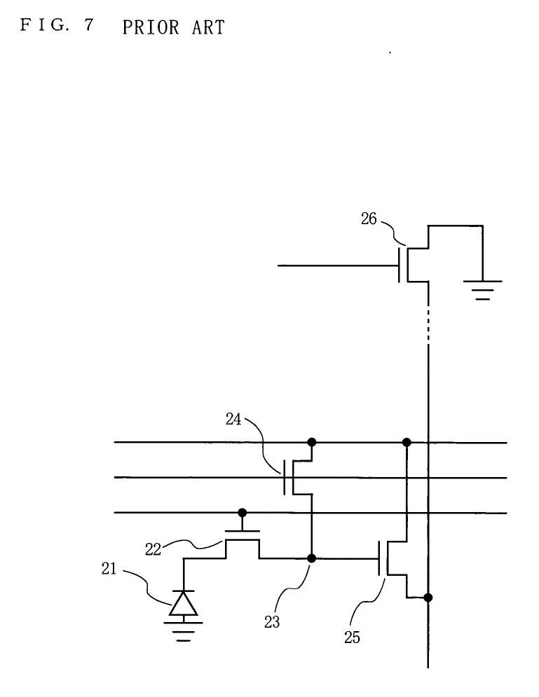

FIG. 6 shows an example of a modified layout of pixels according to the present embodiment. A configuration of the pixels in this example is different from that shown in FIG. 4 in that there is no selection transistor. In this case, pixel selection is conducted by increasing a potential of the FD section 3.

While the invention has been described in detail, the foregoing description is in all aspects illustrative and not restrictive. It is understood that numerous other modifications and variations can be devised without departing from the scope of the invention.

What is claimed is:

1. A solid-state imaging device including a pixel region with a plurality of pixels arrayed and a peripheral circuit for driving or scanning the pixels,
the pixels comprising at least:
a photodiode;
a transfer gate electrode for transferring charges accumulated in the photodiode;
a floating diffusion section for accumulating the charge transferred by the transfer gate electrode;
an amplification transistor in which a gate electrode is connected to the floating diffusion section; and
a reset transistor for resetting a potential of the floating diffusion section, wherein
a gate length of the amplification transistor is shorter than a gate length of a transistor, among transistors comprising the peripheral circuit, whose gate insulating film thickness is a same as a gate insulating film thickness of the amplification transistor and which has a minimum gate length.

2. A solid-state imaging device including a pixel region with a plurality of pixels arrayed and a peripheral circuit for driving or scanning the pixels,
the pixels comprising at least:
a photodiode;
a transfer gate electrode for transferring charges accumulated in the photodiode;
a floating diffusion section for accumulating the charge transferred by the transfer gate electrode;
an amplification transistor in which a gate electrode is connected to the floating diffusion section; and
a reset transistor for resetting a potential of the floating diffusion section, wherein
a gate length of the amplification transistor is shorter than gate lengths of other transistors in the pixels.

3. The solid-state imaging device according to one of claims 1 and 2, wherein at least two neighboring pixels among the plurality of pixels share at least the amplification transistor and the reset transistor.

4. The solid-state imaging device according to claim 3, wherein a selection transistor for selecting an output from each of the two neighboring pixels is further provided.
